(19) United States
(12) Patent Application Publication
(10) Pub. No.: US 2025/0347878 A1
(43) Pub. Date: Nov. 13, 2025

(54) OPTICAL DEVICES AND METHODS OF MANUFACTURE

(71) Applicant: Taiwan Semiconductor Manufacturing Co., Ltd., Hsinchu (TW)

(72) Inventors: Chen-Hua Yu, Hsinchu (TW); Tsung-Fu Tsai, Changhua City (TW); Szu-Wei Lu, Hsinchu (TW); Jiun Yi Wu, Zhongli City (TW)

(21) Appl. No.: 19/278,540

(22) Filed: Jul. 23, 2025

Related U.S. Application Data
(63) Continuation of application No. 18/736,253, filed on Jun. 6, 2024.
(60) Provisional application No. 63/624,500, filed on Jan. 24, 2024.
(60) Provisional application No. 63/557,688, filed on Feb. 26, 2024.

(51) Int. Cl. G02B 6/43; G02B 6/42; H01L 25/065

(52) U.S. Cl. CPC G02B 6/43; G02B 6/4272; G02B 6/4283; H01L 25/0652

(57) ABSTRACT

Optical devices and methods of manufacture are presented in which optical interposers are embedded within interposers. In some embodiments a method includes embedding an optical interposer into an interposer with one or more waveguides, with or without other semiconductor devices, and then bonding one or more semiconductor devices onto the interposer.

### PRIORITY CLAIM AND CROSS-REFERENCE

This application is a continuation of U.S. patent application Ser. No. 18/736,253, filed Jun. 6, 2024, which application claims the benefit of U.S. Provisional Application No. 63/557,688, filed on Feb. 26, 2024, entitled “S_UHB Structure,” and U.S. Provisional Application No. 63/624,500, filed on Jan. 24, 2024, entitled, “S_UHB Structure,” which applications are hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an optical device embedded in an interposer, in accordance with some embodiments.

FIG. 2 illustrates a second optical device embedded in the interposer, in accordance with some embodiments.

FIG. 3 illustrates a thermal die attached over the interposer, in accordance with some embodiments.

FIG. 4 illustrates an optical amplifier embedded in the interposer, in accordance with some embodiments.

FIG. 5 illustrates a laser die embedded in the interposer, in accordance with some embodiments.

FIG. 6 illustrates third semiconductor devices embedded in the interposer, in accordance with some embodiments.

FIG. 7 illustrates the third semiconductor devices embedded in the interposer with the second optical device, in accordance with some embodiments.

FIG. 8 illustrates the third semiconductor devices embedded in the interposer with the laser die, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which an optical interposer is embedded within an interposer that also comprises waveguides in order to provide optical interconnections between optical devices. However, the embodiments presented herein are intended to be illustrative and are not intended to limit the embodiments to the precise descriptions as discussed. Rather, the embodiments discussed may be incorporated into a wide variety of implementations, such as silicon photonics in general, or 3-D ICs with photonic applications, and all such implementations are fully intended to be included within the scope of the embodiments.

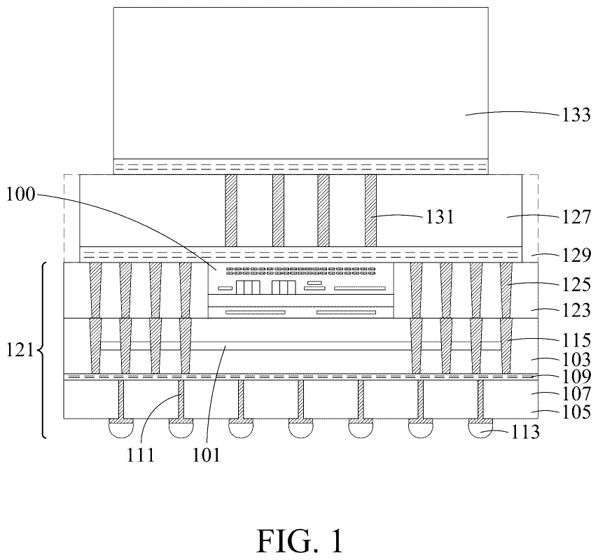

With reference now to FIG. 1, there is illustrated an optical interposer 100 incorporated into and embedded within an interposer 121, in accordance with some embodiments. In the particular embodiment illustrated in FIG. 1, the optical interposer 100 is a photonic integrated circuit (PIC) and comprises a first active layer of first optical components such as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. In an embodiment the first active layer of the first optical components may be located over a dielectric layer, such as a buried oxide. However, any suitable first optical components and any suitable substrate (or lack thereof) may be used.

The optical interposer 100 may further include first metallization layers located over the first optical devices in order to provide electrical connections and electrically connect the first active layer of the first optical components to control circuitry. Additionally, first through device vias may extend from the first metallization layers through the first active layer of the first optical components and to another side of the optical interposer 100. In some embodiments the first metallization layers may further include second optical components along with the conductive and dielectric layers. The second optical components may be similar to the first optical components, such as by being waveguides, couplers, etc. However, any suitable devices may be utilized.

In order to provide a bonding surface the optical interposer 100 may further comprise a first bonding layer over the first metallization layers. In an embodiment the first bonding layer may be used, e.g., for a dielectric-to-dielectric and metal-to-metal bond. In accordance with some embodiments, the first bonding layer is formed of a first dielectric material such as silicon oxide, silicon nitride, or the like. The first dielectric material may be deposited using any suitable method, such as CVD, high-density plasma chemical vapor deposition (HDPCVD), PVD, atomic layer deposition (ALD), or the like. However, any suitable materials and deposition processes may be utilized.

First openings are formed in the first dielectric material to expose conductive portions of the underlying layers (e.g., the first metallization layers) in preparation to form first bond pads. Once the first openings have been formed within the first dielectric material, the first openings may be filled with a seed layer and a plate metal to form the first bond pads within the first dielectric material. The seed layer may be blanket deposited over top surfaces of the first dielectric material and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first dielectric material and sidewalls of the openings and the second openings before the seed layer. The barrier layer may comprise titanium, titanium nitride, tantalum, tantalum nitride, or the like.

Following the filling of the first openings, a planarization process, such as a chemical mechanical polishing (CMP) process, is performed to remove excess portions of the seed layer and the plate metal, forming the first bond pads within the first bonding layer. In some embodiments a bond pad via (not separately illustrated) may also be utilized to connect the first bond pads with underlying conductive portions and, through the underlying conductive portions, connect the first bond pads with the first metallization layers.

Optionally, the first bonding layer may also include one or more third optical components (not separately illustrated in FIG. 1) incorporated within the first bonding layer. In such an embodiment, prior to the deposition of the first dielectric material, the one or more third optical components may be manufactured using similar methods and similar materials as the one or more second optical components (described above), such as by being waveguides and other structures. However, any suitable structures, materials and any suitable methods of manufacture may be utilized.

In some embodiments the optical interposer 100 may also comprise a first mirror in order to direct optical signals (not separately illustrated in FIG. 1) into and out of the first optical components (e.g., into and out of an edge coupler within the first optical components), the second optical components, and/or the third optical components. In an embodiment the first mirror may be a single layer of a mirror coating or else may be a multiple layer structure such as a Bragg's reflector comprising alternating layers of silicon dioxide and amorphous silicon.

Optionally, a second active layer of fourth optical components may be located on a back side of the first active layer opposite the first metallization layer so that the optical interposer has both front and backside waveguides, such as ultra low loss waveguides. In an embodiment the second active layer of fourth optical components may be similar to the second optical components of the first metallization layers. For example, the second active layer of fourth optical components may be alternating layers of a cladding material such as silicon oxide and core material such as silicon nitride to form optical components such as waveguides and the like.

Additionally, in embodiments in which the second active layer has been formed, second through device vias (TDVs), a second metallization layer, and a second bonding layer may be formed. In an embodiment the second through device vias may be similar to the first through device vias, the second metallization layer may be similar to the first metallization layer, and the second bonding layer may be similar to the first bonding layer.

Once the optical interposer 100 has been formed, the optical interposer 100 may be embedded into the interposer 121. In an embodiment, other than the optical interposer 100, the interposer 121 may further comprise fifth optical components 101 located within a third dielectric layer 103 comprising cladding material, and third TDVs 115 through the third dielectric layer 103. The interposer 121 may further comprise an interposer substrate 105 with a semiconductor substrate 107, third metallization layers 109, fourth through device vias (TDVs) 111, and second external connections 113, such as solder bumps.

Optionally, first active devices (not separately illustrated) may be added to the semiconductor substrate 107. The first active devices comprise a wide variety of active devices and passive devices such as capacitors, resistors, inductors and the like that may be used to generate the desired structural and functional requirements of the design for the semiconductor substrate. In other embodiments the interposer 121 remains passive and provides connectivity (both electrical and optical), but no active functions.

The optical interposer 100 may be bonded to the third dielectric layer 103 on an opposite side of the third dielectric layer 103 from the interposer substrate 105. In an embodiment the optical interposer 100 may be bonded using, e.g., a dielectric-to-dielectric and metal-to-metal bonding process. However, any other suitable process, such as a dielectric-to-dielectric bonding process, may be utilized.

In a particular embodiment which utilizes a dielectric-to-dielectric and metal-to-metal bonding process, the bonding process may be initiated by activating the surfaces of the optical interposer 100 and the third dielectric layer 103. Activating the surfaces of the optical interposer 100 and the third dielectric layer 103 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments.

After the activation process the surfaces of the optical interposer 100 and the third dielectric layer 103 may be cleaned using, e.g., a chemical rinse, and then the optical interposer 100 is aligned and placed into physical contact with the third dielectric layer 103. The optical interposer 100 and the third dielectric layer 103 are then subjected to thermal treatment and contact pressure to bond the optical interposer 100 and the third dielectric layer 103. For example, the optical interposer 100 and the third dielectric layer 103 may be subjected to a pressure of about 200 kPa or less, and a temperature between about 25° C. and about 250° C. to fuse the optical interposer 100 and the third dielectric layer 103. The optical interposer 100 and the third dielectric layer 103 may then be subjected to a temperature at or above the eutectic point for material of the bond pads, e.g., between about 150° C. and about 650° C., to fuse the metal. In this manner, the optical interposer 100 and the third dielectric layer 103 form a dielectric-to-dielectric and metal-to-metal bonded device. In some embodiments, the bonded structures are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

In other embodiments in which there are no bond pads on the side of the optical interposer 100 facing the third dielectric layer 103, a dielectric-to-dielectric bonding process may be used. In such an embodiment, the process may also be initiated by activating the surfaces of the optical interposer 100 and the third dielectric layer 103. Activating the top surfaces of the optical interposer 100 and the third dielectric layer 103 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the optical interposer 100 and the third dielectric layer 103.

After the activation process the optical interposer 100 and the third dielectric layer 103 may be cleaned using, e.g., a chemical rinse, and then the optical interposer 100 is aligned and placed into physical contact with the third dielectric layer 103. The optical interposer 100 and the third dielectric layer 103 are then subjected to thermal treatment and contact pressure to bond the optical interposer 100. For example, the optical interposer 100 and the third dielectric layer 103 may be subjected to a pressure of about 200 kPa or less, and a temperature between about 25° C. and about 250° C. to fuse the optical interposer 100 and the third dielectric layer 103. In this manner, the optical interposer 100 and the third dielectric layer 103 form a dielectric-to-dielectric bonded device, but without the metal-to-meal bonds. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

A first gap-fill material 123 may be located around the optical interposer 100 in order to fill the space around the optical interposer 100 and provide additional support, and fifth TDVs 125 extend through the first gap-fill material 123 to make connection to the third TDVs 115. In an embodiment the first gap-fill material 123 may be a material such as silicon oxide, silicon nitride, silicon oxynitride, combinations of these, or the like, deposited to fill and overfill the spaces around the optical interposer 100. Once the first gap-fill material 123 has been deposited, the first gap-fill material 123 may be planarized in order to expose the optical interposer 100, and the fifth TDVs 125 may be formed.

One or more first semiconductor devices 127 may be bonded to the optical interposer 100 and the fifth TDVs 125 and a second gap-fill material 129 may be located around the one or more first semiconductor devices 127. In an embodiment the first semiconductor device 127 is an electronic integrated circuit (EIC) without photonic components. For example, in a particular embodiment the first semiconductor device 127 may be a logic device, an ASIC device, a memory device such as a high bandwidth memory (HBM) module, a hybrid memory cube (HMC) module, xPU, a 3DIC die, a CPU, a GPU, a SoC die, a MEMS die, combinations of these, or the like. Any suitable device with any suitable functionality may be used, and all such devices are fully intended to be included within the scope of the embodiments.

In a particular embodiment in which the first semiconductor device 127 is a logic device, the first semiconductor device 127 may comprise a semiconductor substrate (similar to the semiconductor substrate 107), active devices on the semiconductor substrate, a fourth metallization layer (similar to the first metallization layer), a third bonding layer (similar to the first bonding layer), and sixth TDVs 131 (similar to the first TDVs) extending through the semiconductor substrate. However, any suitable devices and combination of devices may be utilized.

In an embodiment the first semiconductor device 127 may be bonded to the optical interposer 100, the first gap-fill material 123, and the fifth TDVs 125. In a particular embodiment the first semiconductor device 127 may be bonded to the optical interposer 100, the first gap-fill material 123 and the fifth TDVs 125 using a dielectric-to-dielectric and metal-to-metal bonding process similar to the process described above. Once the first semiconductor device 127 has been bonded, the second gap-fill material 129 may be deposited or otherwise placed around the first semiconductor device 127. However, any suitable bonding process may be utilized.

FIG. 1 additionally illustrates a second semiconductor device 133 bonded to the first semiconductor device 127. In an embodiment the second semiconductor device 133 is another electronic integrated circuit (EIC) without photonic components. For example, in a particular embodiment the second semiconductor device 133 may be a memory device, a logic device, an ASIC device, a high bandwidth memory (HBM) module, a hybrid memory cube (HMC) module, xPU, a 3DIC die, a CPU, a GPU, a SoC die, a MEMS die, combinations of these, or the like. Any suitable device with any suitable functionality, may be used, and all such devices are fully intended to be included within the scope of the embodiments.

In a particular embodiment in which the second semiconductor device 133 is a memory device, the second semiconductor device 133 may comprise a semiconductor substrate (similar to the semiconductor substrate 107), active devices on the semiconductor substrate, a fifth metallization layer (similar to the first metallization layer), and a fourth bonding layer (similar to the first bonding layer). However, any suitable devices and combination of devices may be utilized.

The second semiconductor device 133 may be bonded to the first semiconductor device 127 and/or the second gap-fill material 129. In a particular embodiment the second semiconductor device 133 may be bonded to the first semiconductor device 127 using, e.g., a dielectric-to-dielectric and metal-to-metal bonding process. However, any suitable bonding process, such as solder bonding, may also be utilized.

By embedding the optical interposer 100 into the interposer 121 so that a waveguide bridge routing is located within the interposer 121, the size of the optical interposer 100 is no longer restrained by the presence of adjacent dies (e.g., the first semiconductor device 127). As such, the optical interposer 100 may be designed and manufactured to a larger dimension. Additionally, all of the waveguides can be manufactured using ultra low loss waveguides, instead of having a combination of low loss and ultra low loss waveguides.

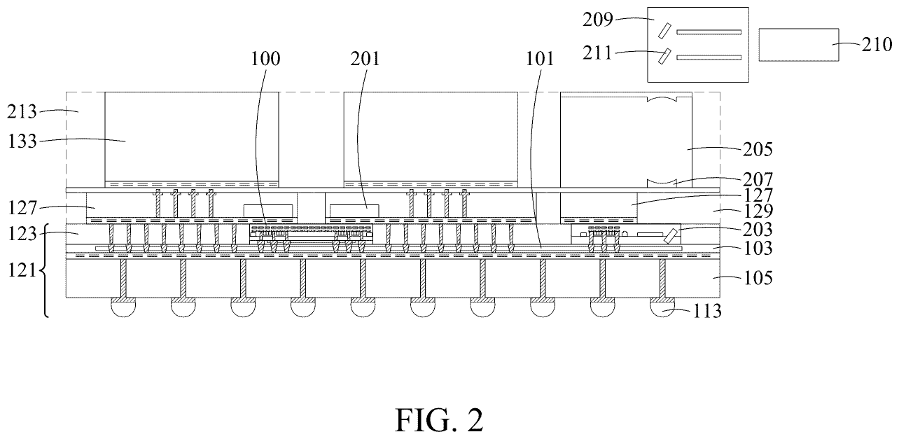

FIG. 2 illustrates another embodiment in which the fifth optical components 101 are utilized to couple to the optical interposer 100. In this embodiment, multiple ones of the first semiconductor device 127 (e.g., logic dies) are connected to the optical interposer 100, so that the optical interposer 100 can send and receive signals to electronic circuitry on both of the first semiconductor devices 127. Additionally, multiple ones of the second semiconductor device 133 (e.g., memory dies) are bonded to individual ones of the first semiconductor devices 127. However, any suitable number and configuration of devices may be utilized.

Additionally in this embodiment, the first semiconductor devices 127 may further comprise a first section 201 that is specifically utilized to communicate with the optical interposer 100, while other sections of the first semiconductor devices 127 are utilized for other logic functions. In some embodiments the first section 201 comprises input/output and/or control circuitry to help send and receive signals (e.g., optical signals or electrical signals) or otherwise assist with the control of the optical components located within the optical interposer 100. However, any suitable circuitry may be utilized.

FIG. 2 additionally illustrates a second optical interposer 203. In an embodiment the second optical interposer 203 may be similar to the optical interposer 100, and may have, e.g., the first mirror. In an embodiment the second optical interposer 203 may be bonded to the third dielectric layer 103 and embedded into the interposer 121 in a similar manner as the optical interposer 100 (e.g., a dielectric-to-dielectric bonding process or a dielectric-to-dielectric and metal-to-metal bonding process). However, any suitable process may be utilized.

Additionally, in embodiments in which the second optical interposer 203 is utilized, the second optical interposer 203 may be used to send and/or receive optical signals from outside of the device using, e.g., a lens die 205. In an embodiment the lens die 205 may be a support material that is transparent to the wavelength of light that is desired to be used, such as silicon, and may be attached over the second optical interposer 203 and the first semiconductor devices 127 using, e.g., an adhesive (not separately illustrated in FIG. 2). However, in other embodiments the lens die 205 may be bonded using, e.g., a bonding process. Any suitable method of attaching the lens die 205 may be used.

The lens die 205 additionally comprises coupling lenses 207 positioned to facilitate movement from a fiber array unit 209 to the second optical interposer 203. In an embodiment the coupling lenses 207 may be formed by shaping the material of the support substrate (e.g., silicon) using masking and etching processes. However, any suitable process may be utilized.

Once the second semiconductor device 133 has been bonded to the first semiconductor device 127, the second semiconductor device 133 is encapsulated with an encapsulant 213. In an embodiment the encapsulant 213 may be a material such as a molding compound placed using an injection molding process. Once in place, the molding compound may be cured and planarized. However, any suitable material and process may be used.

Additionally, a fiber array unit (FAU) 209 provides an ingress and egress to optical signals (not separately illustrated in FIG. 2). In an embodiment the fiber array unit assembly 209 receives optical fibers 210, arranges the optical fibers 210 with a fiber sheath, and directs optical signals from the optical fibers 210 towards one or more deflection mirrors 211 aligned with the first mirror within the second optical interposer 203. Support materials such as glass portions and/or a silicon substrate support the one or more deflection mirrors 211 and optical fibers 210 and may be held together with an index matching gel.

By embedding the optical interposer 100 into the interposer 121 so that waveguide bridge routing is located within the interposer 121, the size of the optical interposer 100 is no longer restrained by the presence of adjacent dies (e.g., the first semiconductor device 127 which are located in a separate layer than the optical interposer 100 and the second optical interposer 203). As such, the optical interposer 100 and the second optical interposer 203 may be designed and manufactured to a larger dimension as desired for the overall design. Additionally, all of the waveguides can be manufactured using ultra low loss waveguides, instead of having a combination of low loss and ultra low loss waveguides.

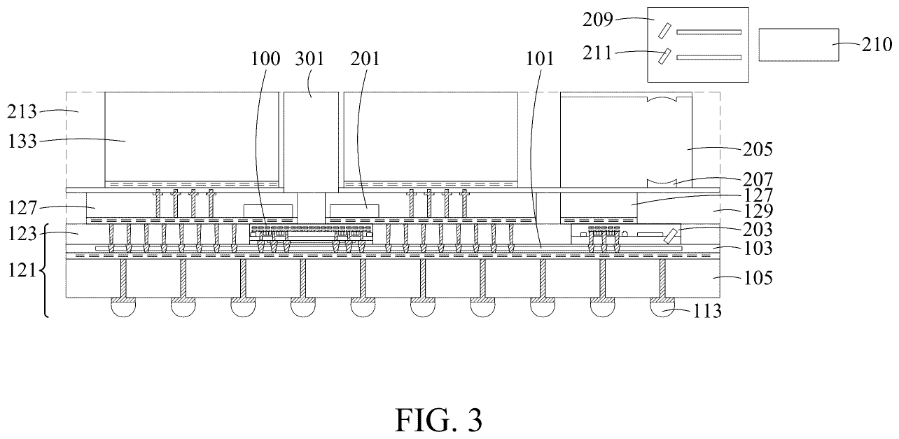

FIG. 3 illustrates another embodiment which is similar to the embodiment illustrated above with respect to FIG. 2. In this embodiment, however, a thermal die 301 may be bonded over the optical interposer 100 and in between the second semiconductor devices 133 in order to help remove heat. In an embodiment the thermal die 301 comprises thermally conductive material that receives heat from the optical interposer 100 and the first semiconductor device 127 and transmits the heat away from the structure. In an embodiment the thermal die 301 may be passive (with only passive transfer of thermal energy) or may comprise an active transfer system which circulates a cooling medium such as water through the thermal die 301 in order to actively remove heat.

Additionally, while the thermal die 301 may comprise materials and structures solely designed for the purpose of removing heat, embodiments are not intended to be limited as such. Rather, in other embodiments the thermal die 301 may comprise active devices (such as transistors) and passive devices (such as resistors and capacitors) which may work to provide a desired functionality (e.g., a logic die) along with the desired removal of heat. Any suitable combination of structures may be utilized with the thermal die 301 in order to remove heat.

In an embodiment the thermal die 301 may be bonded to the second gap-fill material 129 and the first semiconductor devices 127. In a particular embodiment the thermal die 301 may be bonded using a dielectric-to-dielectric and metal-to-metal bonding process. However, in other embodiments, such as when the thermal die 301 comprises active devices and works as a logic die, the thermal die 301 may be bonded with a solder bonding process. Any suitable process may be utilized.

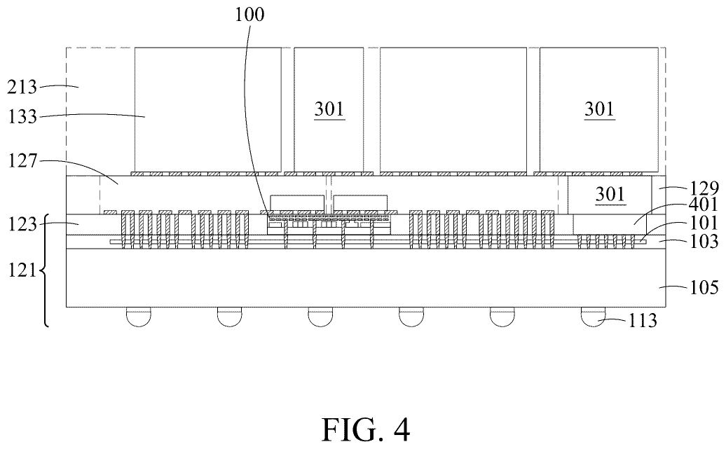

FIG. 4 illustrates another embodiment similar the embodiment illustrated in FIG. 3, but in which an optical amplifier 401 is incorporated and embedded within the interposer 121 in addition to the second optical interposer 203 (not illustrated in the particular cross-sectional view illustrated in FIG. 4). In an embodiment the optical amplifier 401 is utilized to receive weak optical signals and amplify them in order to help ensure that the optical signals can be reliably transmitted throughout the device. In an embodiment the optical amplifier 401 may be a silicon optical amplifier wherein optical amplifiers such as III-V semiconductor optical amplifiers and waveguides are formed on a silicon wafer and diced to form the optical amplifier 401. However, any suitable devices may be utilized.

Once the optical amplifier 401 has been formed, the optical amplifier 401 may be bonded to the third dielectric layer 103 and embedded within the interposer 121. In an embodiment the optical amplifier 401 may be bonded to the third dielectric layer 103 using a similar process as the optical interposer 100 (e.g., a dielectric-to-dielectric and metal-to-metal bonding process). However, any suitable process may be utilized.

FIG. 4 additionally illustrates that, once the optical amplifier 401 has been formed, bonded, and covered with the first gap-fill material 123, another thermal die 301 may be bonded over the optical amplifier 401 in order to help remove heat. In an embodiment the thermal die 301 comprises thermally conductive material that receives heat from the optical amplifier 401 and transmits the heat away from the optical amplifier 401. In an embodiment the thermal die 301 may be passive (with only passive transfer of thermal energy) or may comprise an active transfer system which circulates a cooling medium such as water through the thermal die 301 in order to actively move heat away from the optical amplifier 401.

Additionally, while the thermal die 301 may comprise materials and structure solely designed for the purpose of removing heat, embodiments are not intended to be limited as such. Rather, in other embodiments the thermal die 301 may comprise active devices (such as transistors) and passive devices (such as resistors and capacitors) which may work to provide a desired functionality along with the desired removal of heat. Any suitable combination of structures may be utilized with the thermal die 301 in order to remove heat from the optical amplifier 401.

Additionally, once the thermal die 301 has been placed onto the optical amplifier 401, the first semiconductor devices 127 may be bonded, and the thermal die 301 and the first semiconductor devices 127 may be covered with the second gap-fill material 129. Once the second gap-fill material 129 has been placed, the second semiconductor devices 133 may be attached, and additional thermal dies 301 may be placed. For example, another thermal die 301 may be used to remove heat from the thermal die 301 adjacent to the optical amplifier 401, while yet another thermal die 301 may be positioned to help remove heat from the optical interposer 100. However, any suitable number and arrangement of thermal dies 301 may be utilized, and all such arrangements are fully intended to be included within the scope of the embodiments.

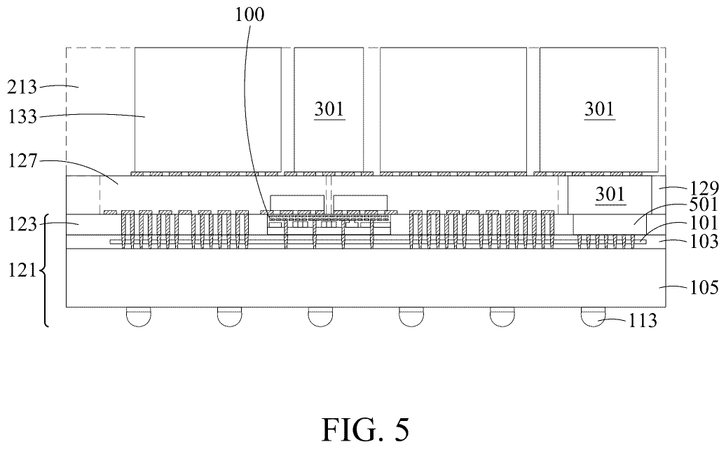

FIG. 5 illustrates another embodiment similar the embodiment illustrated in FIG. 4, but in which a laser die 501 is incorporated and embedded into the interposer 121 in addition to the second optical interposer 203 and the optical amplifier 401 (not illustrated in the cross-sectional view of FIG. 5). In an embodiment, the laser die 501 is utilized to provide a power source for the optical devices throughout the device instead of receiving laser power separately from off of the device. In some embodiments, the laser die 501 may comprise light generating structures such as one or more laser diodes (not separately illustrated in FIG. 5) surrounded by dielectric and/or cladding material over a substrate. In particular embodiments the laser diodes may be Fabry-Perot Diodes, and may be based on III-V materials, II-VI materials, or any other suitable set of materials.

Once the laser die 501 has been formed, the laser die 501 may be bonded to the third dielectric layer 103 so that light can be coupled into the fifth optical components 101 of the interposer 121. In an embodiment the laser die 501 may be bonded using a similar process as the optical interposer 100 (e.g., a dielectric-to-dielectric and metal-to-metal bonding process). Additionally, once the laser die 501 has been bonded the thermal dies 301 may be attached to the laser die 501 in order to assist in removing heat. However, any suitable process may be utilized.

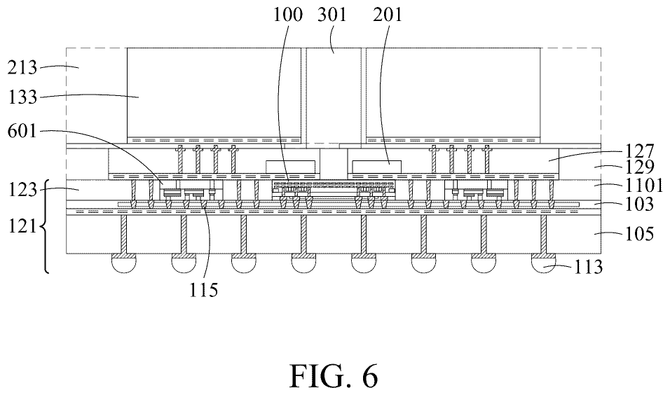

FIG. 6 illustrates another embodiment that is similar to the embodiment illustrated above with respect to FIG. 3, but without the second optical interposer 203, the first semiconductor devices 127 overlying the second optical interposer 203, and the lens die 205. In this embodiment, instead of having the second optical interposer 203, the first semiconductor devices 127 overlying the second optical interposer 203, and the lens die 205, the structure includes one or more third semiconductor devices 601 that are also embedded within the interposer 121. In an embodiment the third semiconductor devices 601 are electronic integrated circuits (EICs) without photonic components. For example, in a particular embodiment the third semiconductor device 601 may be a metal-insulator-metal (MIM) device, an ASIC device, a memory device such as a high bandwidth memory (HBM) module, a hybrid memory cube (HMC) module, xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

The third semiconductor devices 601 may be embedded within the interposer 121 in order to connect the third semiconductor devices 601 to the third TDVs 115. In a particular embodiment the third semiconductor devices 601 are bonded to the third dielectric layer 103 and the third TDVs 115 using, e.g., a dielectric-to-dielectric and metal-to-metal bonding process. Additionally, the third semiconductor devices 601 may be surrounded by the first gap-fill material 123 and bonded and connected to one or more of the first semiconductor devices 127. However, any suitable arrangement may be utilized.

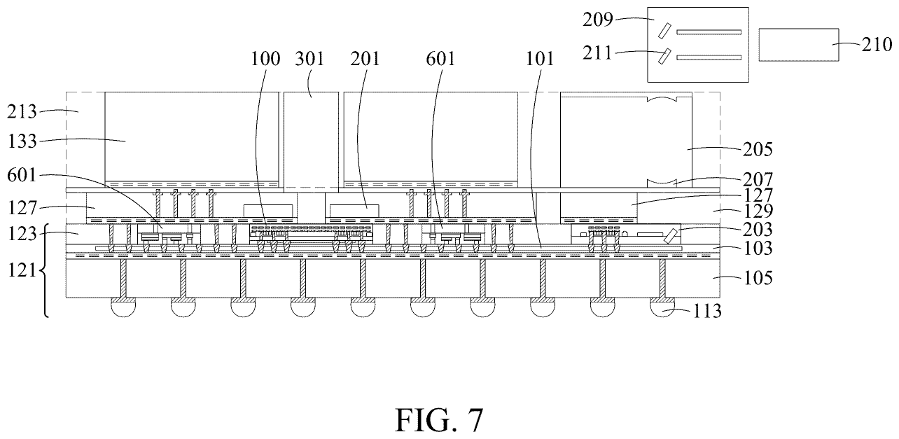

FIG. 7 illustrates another embodiment which utilizes the third semiconductor devices 601 embedded within the interposer 121 similar to the embodiment illustrated above with respect to FIG. 6. In this embodiment, in addition to the third semiconductor devices 601 being embedded within the interposer 121, the second optical interposer 203 is also embedded within the interposer 121. Additionally, the first semiconductor devices 127 and the lens die 205 are placed over the second optical interposer 203. However, any suitable devices may be utilized.

Additionally, in a particular embodiment each of the optical interposer 100, the second optical interposer 203, and the third semiconductor devices 601 are bonded to the third dielectric layer 103 using, e.g., a dielectric-to-dielectric and metal-to-metal bonding process. Additionally, the first semiconductor devices 127 may also be bonded using a dielectric-to-dielectric and metal-to-metal bonding process, and the second semiconductor devices 133, the thermal dies 301, and the lens die 205 are also bonded using a dielectric-to-dielectric and metal-to-metal bonding process. However, any suitable bonding processes may be utilized.

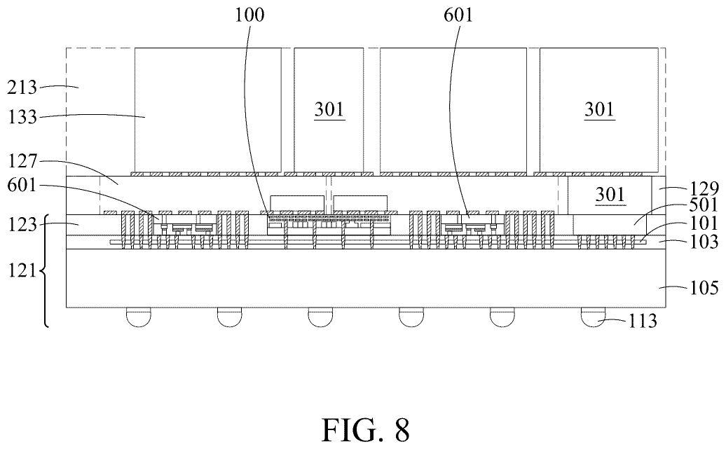

FIG. 8 illustrates another embodiment which utilizes the third semiconductor devices 601 embedded within the interposer 121 similar to the embodiment illustrated above with respect to FIG. 6. In this embodiment, however, in addition to the third semiconductor devices 601 being embedded within the interposer 121, the laser die 501 is also embedded within the interposer 121. Additionally, the thermal dies 301 are placed over the laser die 501. However, any suitable devices may be utilized.

Additionally, in a particular embodiment each of the optical interposer 100, the laser die 501, and the third semiconductor devices 601 are bonded to the third dielectric layer 103 using, e.g., a dielectric-to-dielectric and metal-to-metal bonding process. Also in this embodiment, the first semiconductor devices 127 and the thermal die 301 over the laser die 501 may also be bonded using a dielectric-to-dielectric and metal-to-metal bonding process, and the second semiconductor devices 133 and the thermal dies 301 are also bonded using a dielectric-to-dielectric and metal-to-metal bonding process. However, any suitable bonding processes may be utilized.

By embedding the optical interposer 100 into the interposer 121 so that a waveguide bridge routing is located within the interposer 121, the size of the optical interposer 100 is no longer restrained by the presence of adjacent dies (e.g., the first semiconductor device 127). As such, the optical interposer 100 may be designed and manufactured to a larger dimension. Additionally, all of the waveguides can be manufactured using ultra low loss waveguides, instead of having a combination of low loss and ultra low loss waveguides.

In an embodiment, a method of manufacturing an optical device includes: receiving an optical interposer, the optical interposer comprising a first waveguide; and embedding the optical interposer into an interposer, wherein the interposer comprises a second waveguide optically coupled to the first waveguide. In an embodiment the method further includes embedding a first semiconductor device into the interposer. In an embodiment the first semiconductor device is a metal-insulator-metal die. In an embodiment the method further includes bonding a logic die to the interposer. In an embodiment the method further includes bonding a memory die to the logic die. In an embodiment the method further includes embedding an optical amplifier die into the interposer. In an embodiment the method further includes: embedding a second optical interposer into the interposer; and attaching a lens die over the second optical interposer.

In another embodiment, an optical device includes: a waveguide; a dielectric material over the waveguide; an optical interposer bonded to the dielectric material; a first gap-fill material around the optical interposer; a first through via extending through the first gap-fill material; a logic die bonded to the second through via; and a memory die bonded to the logic die. In an embodiment the optical device further includes a first semiconductor die bonded to the dielectric material. In an embodiment the optical device further includes a second optical interposer bonded to the dielectric material. In an embodiment the optical device further includes a lens die over the second optical interposer. In an embodiment the second optical interposer comprises a first mirror. In an embodiment the optical device further includes an optical amplifier die bonded to the dielectric material. In an embodiment the optical device further includes a thermal die over the optical amplifier die.

In yet another embodiment an optical device includes: an interposer comprising a first waveguide; and an optical interposer embedded within the interposer, the optical interposer comprising a second waveguide coupled to the first waveguide. In an embodiment the optical device further includes a thermal die located over the optical interposer. In an embodiment the optical device further includes an amplifier die embedded within the interposer. In an embodiment the optical device further includes a metal-insulator-metal die embedded within the interposer. In an embodiment the optical device further includes a logic die bonded to the interposer. In an embodiment the optical device further includes a memory die bonded to the logic die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an optical device, the method comprising:
forming an optical interposer, the optical interposer comprising a first waveguide; and
embeddding the optical interposer into an interposer, wherein the interposer comprises a second waveguide optically coupled to the first waveguide.

2. The method of claim 1, wherein the embedding the optical interposer comprises:
bonding the optical interposer to a dielectric material; and
depositing a gap-fill material around the optical interposer.

3. The method of claim 2, further comprising forming first through vias extending through the gap-fill material.

4. The method of claim 3, wherein the forming the first through vias forms the first through vias in physical contact with second through vias.

5. The method of claim 4, wherein the interposer comprises a semiconductor substrate.

6. The method of claim 5, wherein the bonding the optical interposer comprises a dielectric-to-dielectric and metal-to-metal bonding process.

7. The method of claim 1, further comprising bonding a semiconductor die over the optical interposer.

8. A method of manufacturing an optical device, the method comprising:
depositing a dielectric material over a waveguide;
bonding an optical interposer to the dielectric material;
depositing a first gap-fill material around the optical interposer;
forming a first through via extending through the first gap-fill material;
bonding a logic die to the first through via; and
bonding a memory die to the logic die.

9. The method of claim 8, wherein the bonding the optical interposer is performed at least in part with a dielectric-to-dielectric and metal-to-metal bonding process.

10. The method of claim 8, further comprising depositing a second gap-fill material around the logic die.

11. The method of claim 10, wherein the bonding the memory die comprises bonding the memory die to the second gap-fill material.

12. The method of claim 8, further comprising bonding a second optical interposer to the dielectric material.

13. The method of claim 12, further comprising bonding a lens die directly over the second optical interposer.

14. The method of claim 13, further comprising, after the bonding the lens die, a second logic die is at least partially disposed between the lens die and the second optical interposer.

15. A method of manufacturing an optical device, the method comprising:
forming an interposer, the interposer comprising a first waveguide;
embedding an optical interposer within the interposer, the optical interposer comprising a second waveguide coupled to the first waveguide;
bonding a first semiconductor die to the interposer; and
bonding a second semiconductor die to the first semiconductor die.

16. The method of claim 15, wherein the first waveguide and the second waveguide are both ultra low loss waveguides.

17. The method of claim 15, further comprising depositing a gap-fill material around the first semiconductor die.

18. The method of claim 17, further comprising bonding a thermal die to the gap-fill material.

19. The method of claim 15, further comprising embedding a laser die within the interposer.

20. The method of claim 15, further comprising embedding a third semiconductor die within the interposer.
